(19) United States
(12) Patent Application Publication
(10) Pub. No.: US 2016/0079240 A1
(43) Pub. Date: Mar. 17, 2016

(54) SEMICONDUCTOR DEVICE

(71) Applicant: Kabushiki Kaisha Toshiba, Tokyo (JP)

(72) Inventor: Naomasa Sugita, Hakusan Ishikawa (JP)

(21) Appl. No.: 14/617,799

(22) Filed: Feb. 9, 2015

(30) Foreign Application Priority Data
Sep. 16, 2014 (JP) 2014-188157

(51) Int. Cl. H01L 27/08; H01L 29/866; H01L 29/06

(52) U.S. Cl. CPC H01L 27/0814; H01L 29/0642; H01L 29/866; H01L 29/0684

(57) ABSTRACT

According to one embodiment, a semiconductor device includes a first semiconductor region, a plurality of second semiconductor regions, a plurality of third semiconductor regions, an isolation region, a first electrode, a second electrode, and a third electrode. The plurality of second semiconductor regions is selectively provided on the first semiconductor region. The second semiconductor region has a first conductivity type. The plurality of third semiconductor regions is selectively provided on the first semiconductor region. Each of the third semiconductor regions is adjacent to each of the second semiconductor regions. The third semiconductor region has a second conductivity type. The isolation region is provided in the first semiconductor region. The isolation region is positioned between the adjacent second semiconductor regions and the adjacent third semiconductor regions. The first electrode is connected to the second semiconductor region and the third semiconductor region which are adjacent to the isolation region.

### CROSS-REFERENCE TO RELATED APPLICATIONS

This application is based upon and claims the benefit of priority from Japanese Patent Application No. 2014-188157, filed on Sep. 16, 2014; the entire contents of which are incorporated herein by reference.

### FIELD

Embodiments described herein relate generally to a semiconductor device.

### BACKGROUND

In electric equipment, a semiconductor device (for example, a Zener diode) is used so as to obtain a constant voltage. A breakdown voltage of a Zener diode has thermal dependency generally. Especially, a breakdown voltage fluctuates largely depending on a change of temperature in a semiconductor device having a high breakdown voltage. If thermal dependency of a breakdown voltage becomes large, the breakdown voltage is largely shifted from a desired value under a low temperature condition or a high temperature condition. As a result, electric equipment using a Zener diode may or may not perform operation normally.

It is desired to compensate for thermal dependency of a breakdown voltage in a semiconductor device.

### BRIEF DESCRIPTION OF THE DRAWINGS

FIG. 1 is a cross-sectional view of a semiconductor device according to a first embodiment;

FIG. 2 is a plan view of the semiconductor device according to the first embodiment;

FIG. 3 is a cross-sectional view of a semiconductor device according to a second embodiment;

FIG. 4 is a cross-sectional view of a semiconductor device according to a third embodiment;

FIG. 5 is a cross-sectional view of a semiconductor device according to a fourth embodiment;

FIG. 6 is a cross-sectional view of a semiconductor device according to a fifth embodiment;

FIG. 7 is a cross-sectional view of a semiconductor device according to a sixth embodiment;

FIG. 8 is a plan view of the semiconductor device according to the sixth embodiment;

FIG. 9 is a cross-sectional view of a semiconductor device according to a seventh embodiment;

FIG. 10 is a plan view of the semiconductor device according to the seventh embodiment;

FIG. 11 is a cross-sectional view of a semiconductor device according to an eighth embodiment;

FIG. 12 is a plan view of the semiconductor device according to the eighth embodiment;

FIG. 13 is a cross-sectional view of a semiconductor device according to a ninth embodiment;

FIG. 14 is a plan view of the semiconductor device according to the ninth embodiment;

FIG. 15 is a plan view of a semiconductor device according to a tenth embodiment;

FIG. 16 is a cross-sectional view of a semiconductor device according to a eleventh embodiment;

FIG. 17 is a plan view of the semiconductor device according to the eleventh embodiment;

FIG. 18 is a cross-sectional view of a semiconductor device according to a twelfth embodiment; and

FIG. 19 is a cross-sectional view of a semiconductor device according to a thirteenth embodiment.

### DETAILED DESCRIPTION

According to one embodiment, a semiconductor device includes a first semiconductor region, a plurality of second semiconductor regions, a plurality of third semiconductor regions, an isolation region, a first electrode, a second electrode, and a third electrode. The plurality of second semiconductor regions is selectively provided on the first semiconductor region. The second semiconductor region has a first conductivity type. The plurality of third semiconductor regions is selectively provided on the first semiconductor region. Each of the third semiconductor regions is adjacent to each of the second semiconductor regions. The third semiconductor region has a second conductivity type. The isolation region is provided in the first semiconductor region. The isolation region is positioned between the adjacent second semiconductor regions and the adjacent third semiconductor regions. The first electrode is connected to the second semiconductor region and the third semiconductor region which are adjacent to the isolation region. The second electrode is connected to the second semiconductor region. The third electrode is connected to the third semiconductor region.

Hereinafter, embodiments of the invention will be described with reference to the accompanying drawings. The drawings are schematic or conceptual. Thus, a relationship between the thickness and the width of each part, a ratio of size of parts or the like in the drawings is not necessarily limited to the same as those in the actual ones. Even when the same parts are shown, dimensions or proportions may be different from those in the drawings.

Arrows X, Y and Z in the respective drawings show three directions orthogonal to each other. For example, a direction shown by the arrow X (X-direction) and a direction shown by the arrow Y (Y-direction) are parallel with a main surface of a semiconductor substrate. A direction shown by the arrow Z (Z-direction) shows a direction vertical to the main surface of the semiconductor substrate.

In the specification and the respective drawings, the same components as components which have been described will be denoted by the same reference numerals and the descriptions thereof will be appropriately omitted.

In the description which will be described later, marks of n⁺, n, p⁺ and p show a relative extent of an impurity concentration in conductivity types of semiconductor. That is, “n⁺” shows that an impurity concentration in an n-type semiconductor is relatively high compared to “n”. “p⁺” shows that an impurity concentration in a p-type semiconductor is relatively high compared to “p”.

Regarding the respective embodiments which will be described later, embodiments in which a p-type and an n-type at a semiconductor region are reversed and polarities of an anode and a cathode are reversed may be implemented.

### First Embodiment

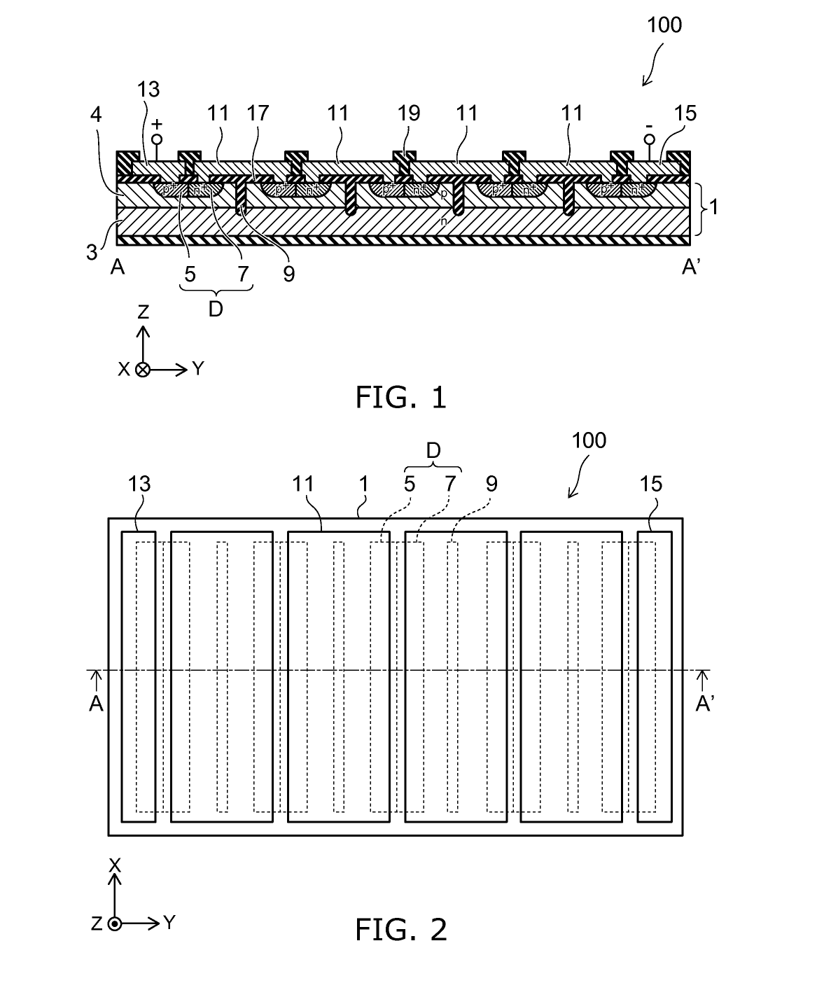

FIG. 1 is a cross-sectional view of a semiconductor device 100 according to a first embodiment.

FIG. 2 is a plan view of the semiconductor device 100 according to the first embodiment.

FIG. 1 is a cross-sectional view taken along line I-I in FIG. 2.

In FIG. 2, an insulating layer, a protective layer and the like are omitted. FIG. 2 illustrates electrodes which are transmitted so as to show a positional relationship between the semiconductor regions and the electrodes. In FIG. 2, the semiconductor regions and isolation regions are shown by broken lines and the electrodes are shown by solid lines.

The semiconductor device 100 includes a semiconductor substrate (semiconductor substrate 1), a first electrode (electrode 11), a second electrode (anode electrode 13), and a third electrode (cathode electrode 15).

The semiconductor substrate has a first semiconductor region (p-type semiconductor region 4), a plurality of diodes, the isolation region (isolation region 9), and a fourth semiconductor region (n-type semiconductor region 3). The diode includes a second semiconductor region (p⁺-type semiconductor region 5) which is a first conductivity type and a third semiconductor region (n⁺-type semiconductor region 7) which is a second conductivity type.

The semiconductor substrate 1 (simply refer to a substrate 1 below) is a substrate formed of silicon as a main component. The semiconductor regions are provided in the substrate 1.

The substrate 1 has the n-type semiconductor region 3. The p-type semiconductor region 4 is provided on the n-type semiconductor region 3. A p-type semiconductor layer is made on an n-type semiconductor substrate containing silicon by using epitaxial growth thereby forming the p-type semiconductor region 4. Additionally, the p-type semiconductor region 4 is formed by performing ion implantation of p-type impurities on a surface of an n-type semiconductor substrate.

The p⁺-type semiconductor region 5 is selectively provided on the p-type semiconductor region 4. The p⁺-type semiconductor region 5 is provided at a surface of the substrate 1. As illustrated in FIG. 2, the p⁺-type semiconductor region 5 extends in the X-direction. A plurality of p⁺-type semiconductor regions 5 are provided in the Y-direction orthogonal to the X-direction.

A concentration of p-type impurities in the p⁺-type semiconductor region 5 is larger than a concentration of p-type impurities in the p-type semiconductor region 4. The concentration of p-type impurities on a surface of the p⁺-type semiconductor region 5 is an impurity concentration of the extent of obtaining electrically ohmic characteristics.

The p⁺-type semiconductor region 5 is formed by, for example, selectively performing ion implantation of p-type impurities on the p-type semiconductor region 4.

The n⁺-type semiconductor region 7 is selectively provided on the p-type semiconductor region 4. The n⁺-type semiconductor region 7 is provided at the surface of the substrate 1. The n⁺-type semiconductor region 7 extends in the X-direction. A plurality of n⁺-type semiconductor regions 7 are provided in the Y-direction. The n⁺-type semiconductor region 7 is adjacent to the p⁺-type semiconductor region 5 in the Y-direction to form a p-n junction. That is, a diode D is configured by the p⁺-type semiconductor region 5 and the n⁺-type semiconductor region 7 which are adjacent to each other. Five diodes D are provided on the p-type semiconductor region 4 in an example shown in FIG. 1.

A concentration of n-type impurities in the n⁺-type semiconductor region 7 is larger than the concentration of the p-type impurities in the p-type semiconductor region 4. The concentration of n-type impurities on a surface of the n⁺-type semiconductor region 7 is an impurity concentration of the extent of obtaining electrically ohmic characteristics, similarly to the p⁺-type semiconductor region 5. The concentration of the n-type impurities in the n⁺-type semiconductor region 7 is, for example, equal to the concentration of the p-type impurities in the p⁺-type semiconductor region 5. The concentration of the n-type impurities in the n⁺-type semiconductor region 7 may be different from the concentration of the p-type impurities in the p⁺-type semiconductor region 5 in order to obtain a function of a diode.

The n⁺-type semiconductor region 7 is formed by, for example, selectively performing ion implantation of n-type impurities in the p-type semiconductor region 4.

The diode D may be formed in an n-type semiconductor region 4 obtained by replacing the n-type semiconductor region 3 with a p-type semiconductor region and replacing the p-type semiconductor region 4 with an n-type semiconductor region.

The isolation region 9 is provided between the diodes D adjacent to each other. The isolation region 9 extends in the X-direction. A plurality of isolation regions 9 are provided in the Y-direction.

In the embodiment, the isolation region 9 is provided to reach the n-type semiconductor region 3 from a surface of the p-type semiconductor region 4 (the surface of the substrate 1). However, the isolation region 9 may or may not reach the n-type semiconductor region 3. When a distance between a tip end of the isolation region 9 and the n-type semiconductor region 3 is short, the semiconductor device 100 may perform operation, similarly to when the isolation region 9 reaches the n-type semiconductor region 3.

The isolation region 9 is formed by, for example, burying an insulating material in a trench formed in the substrate 1.

The electrode 11 is provided on the substrate 1. The electrode 11 is connected to the p⁺-type semiconductor region 5 of one diode D and the n⁺-type semiconductor region 7 of another diode D adjacent to the one diode D. That is, the electrode 11 connects the p⁺-type semiconductor region 5 and the n⁺-type semiconductor region 7 which are adjacent to one isolation region 9. The electrode 11 causes the plurality of the diodes D to be connected to each other in series. That is, the p⁺-type semiconductor region 5 and the n⁺-type semiconductor region 7 which are adjacent to each other through the isolation region 9 are electrically connected to each other.

The electrode 11 extends in the X-direction. A plurality of electrodes 11 are provided in the Y-direction. The electrode 11 extends in the X-direction, similarly to the p⁺-type semiconductor region 5 and the n⁺-type semiconductor region 7. Accordingly, it is possible to increase a contact area of the electrode 11 with the p⁺-type semiconductor region 5 and the n⁺-type semiconductor region 7 and to reduce electrical resistance.

The p⁺-type semiconductor region 5 of a diode which is positioned at an anode end among the plurality of the diodes D connected in series is connected to an anode electrode 13.

The n⁺-type semiconductor region 7 of a diode which is positioned at a cathode end among plurality of the diodes D connected in series is connected to a cathode electrode 15.

For example, metal or polysilicon may be used as a material of the electrode 11, the anode electrode 13, and the cathode electrode 15. Each of the electrodes is configured from Ti which is provided on the substrate 1 and Al which is provided on the Ti in an example when metal is used as the material of the electrodes.

An insulating layer 17 is provided on the substrate 1 at a region other than a contact part of the electrode 11 with the respective semiconductor regions. The insulating layer 17 is, for example, provided between the isolation region 9 and the electrode 11 and provided right on an interface of a p-n junction between the p⁺-type semiconductor region 5 and the n⁺-type semiconductor region 7. For example, silicon oxide may be used as a material of the insulating layer 17.

A protective layer 19 is provided on the electrode 11 and on the insulating layer 17. For example, polyimide may be used as a material of the protective layer 19.

An action and an effect of the embodiment will be described below.

If a positive potential is applied to the anode electrode 13 with respect to the cathode electrode 15, a forward voltage is applied to the respective diodes D. At this time, voltage drop occurs in the respective diodes D. A drop voltage when the forward voltage is applied to the diode varies depending on the temperature. Specifically, the drop voltage is approximately 0.7 V at room temperature. The drop voltage decreases by approximately 2.5 mV for every 1° C. increase in temperature.

When the diodes D are connected in series, thermal dependency of the respective diodes D is summed. For example, five diodes are connected in series, and thus the drop voltage decreases by approximately 12.5 mV for every 1° C. increase in temperature in the semiconductor device shown in FIG. 1.

Accordingly, thermal dependency of the breakdown voltage of a Zener diode can be reduced by assembling of a semiconductor device in which the breakdown voltage increases in accordance with increase in temperature, for example, the semiconductor device 100 in which the number of the diodes D to be connected in series is adjusted with a Zener diode having a breakdown voltage of 5 V or more.

Recently, as a semiconductor device of power control is widely in use, a Zener diode having a high breakdown voltage has been widely in use. The breakdown voltage fluctuates largely depending on the temperature in the Zener diode having a high breakdown voltage. Accordingly, it is impossible to sufficiently compensate for the thermal dependency of a Zener diode which has a high breakdown voltage only by connecting one forward diode. Such a Zener diode is used in, for example, an automobile. When the Zener diode is used in an automobile, the temperature of a semiconductor device varies in a range of −40° C. to 125° C. according to external circumstances. If the thermal dependency is not sufficiently reduced, the breakdown voltage is largely shifted from a value at the room temperature under a low temperature situation or a high temperature situation.

Accordingly, the thermal dependency of the breakdown voltage of a semiconductor device is desired to be reduced as much as possible.

According to the semiconductor device 100 of the embodiment, because the plurality of the diodes D are connected in series, a drop voltage decreasing in accordance with increase in temperature may have a large value. For example, when the semiconductor device is connected to the above-described Zener diode having a high breakdown voltage, it is possible to compensate for the thermal dependency of the Zener diode.

In the embodiment, the isolation region 9 is provided between the diodes D. Accordingly, it is possible to suppress a current from flowing in the n⁺-type semiconductor region 7 which comes into contact with the cathode electrode 15 through the p-type semiconductor region 4 without flowing through the electrode 11. As a result, it is possible to improve reliability in an operation of the semiconductor device 100 as a diode.

The p-type semiconductor region 4 is provided on the n-type semiconductor region 3. The isolation region 9 reaches the n-type semiconductor region 3 from a surface of the p-type semiconductor region 4. Thus, it is possible to further suppress a current from flowing in the n⁺-type semiconductor region 7 which comes into contact with the cathode electrode 15 through the p-type semiconductor region 4 without flowing through the electrode 11 and it is possible to further improve reliability in an operation of the semiconductor device 100 as a diode.

A relative extent of an impurity concentration in the respective semiconductor regions described above in the respective embodiments may be confirmed by using, for example, a scanning capacitance microscopy (SCM). Because a carrier density of each semiconductor region is proportionate to an impurity concentration of each of the semiconductor region.

Thus, in the present embodiment, a density of p-type carrier (a density of hole) in p⁺-type semiconductor region 5 is higher than a density of p-type carrier in p-type semiconductor region 4. A density of n-type carrier (a density of free-electron) in n⁺-type semiconductor region 7 is higher than a density of p-type carrier in p-type semiconductor region 4.

In the embodiments described below, a relative extent of an impurity concentration in the respective semiconductor regions can be similarly understood as a relative extent of an carrier density in the respective semiconductor regions.

### Second Embodiment

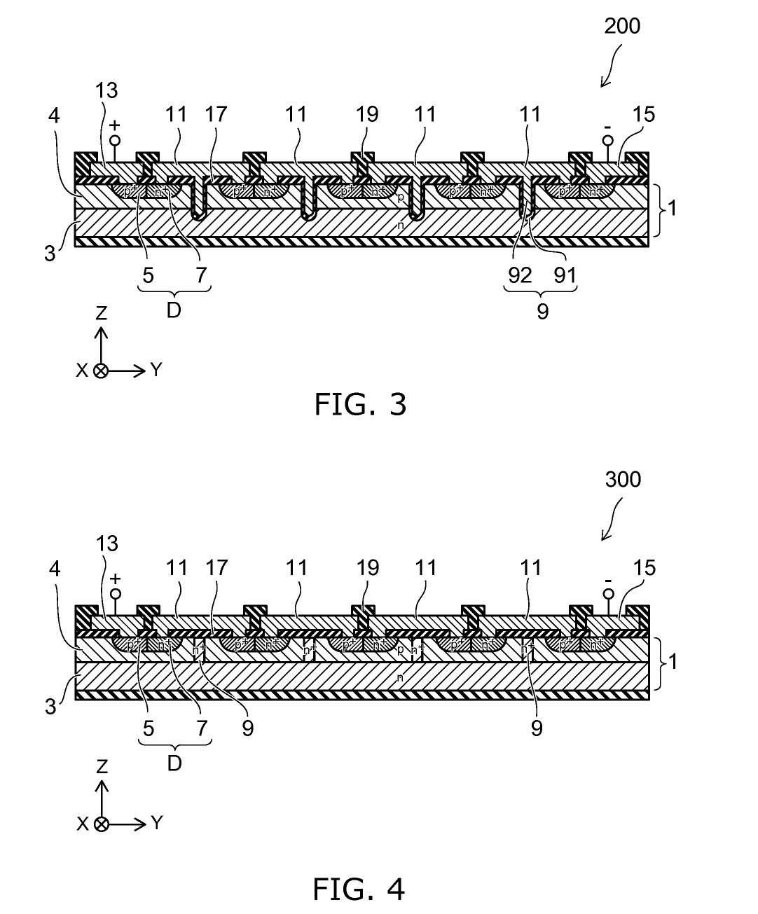

FIG. 3 is a cross-sectional view of a semiconductor device 200 according to a second embodiment.

The semiconductor device 200 according to the second embodiment has a different structure of the isolation region 9 from that of the semiconductor device 100 according to the first embodiment.

In the first embodiment, the isolation region 9 is made of only an insulating material. On the other hand, in the second embodiment, the isolation region 9 is configured from an insulating layer 91 and a conductive layer 92.

The insulating layer 91 has a part connected to the n-type semiconductor region 3 and another part connected to the p-type semiconductor region 4. When the isolation region 9 does not reach the n-type semiconductor region 3, the insulating layer 91 does not come into contact with the n-type semiconductor region 3. That is, the insulating layer 91 has at least one part which is connected to the p-type semiconductor region 4.

The conductive layer 92 is provided through the insulating layer 91 in the n-type semiconductor region 3 and the p-type semiconductor region 4. The isolation region 9 may reach the n-type semiconductor region 3 and the insulating layer 91 may be provided in only the p-type semiconductor region 4. That is, the conductive layer 92 has at least one part which is provided through the insulating layer 91 in the p-type semiconductor region 4.

The conductive layer 92 is connected to the electrode 11.

The isolation region 9 according to the embodiment is formed by, for example, forming a trench to reach the semiconductor region 3 in the substrate 1, putting an insulating material into the trench, and then putting a conductive material into the trench. When the conductive layer 92 is formed, the electrode 11, the anode electrode 13, and the cathode electrode 15 may be formed at the same time.

In an example shown in FIG. 3, the trench formed in the substrate 1 is buried by the conductive layer 92. However, the conductive layer 92 may not bury the trench formed in the substrate 1. In this case, a conductive layer formed on the insulating layer 91 at a part where the isolation region 9 is provided may be the conductive layer 92 or the electrode 11.

Carriers move between the diodes D through the electrode 11 and move in the p-type semiconductor region 4, in a state where a current flows in the diode D. Electric potential of the electrode 11 varies from the anode electrode 13 to the cathode electrode 15 in accordance with the number of the diodes D. A potential difference between the adjacent diodes is substantially equal to a drop voltage of the diodes D. The carriers in the p-type semiconductor region 4 are affected by a current flowing in the diode D which is provided on the p-type semiconductor region 4 or electric potential from the diode D which is adjacent to the p-type semiconductor region 4 and provided on the p-type semiconductor region 4 and the carriers move in the p-type semiconductor region 4. Accordingly, a potential difference of the adjacent p-type semiconductor regions 4 is different from each other in the p-type semiconductor regions 4 in some cases.

In the embodiment, the conductive layer 92 connected to the electrode 11 is provided in the p-type semiconductor region 4. Electric potential in the p-type semiconductor region 4 is stable compared to a case in which the conductive layer 92 is not provided. As a result, it is possible for a diode to stably operate in the semiconductor device 200.

### Third Embodiment

FIG. 4 is a cross-sectional view of a semiconductor device 300 according to a third embodiment.

The semiconductor device 300 according to the third embodiment has a different structure of the isolation region 9 from that of the semiconductor device 100 according to the first embodiment.

In the embodiment, the isolation region 9 is configured with a semiconductor region which is a conductivity type opposite to the conductivity type of the p-type semiconductor region 4. The isolation region 9 reaches the n-type semiconductor region 3 from the surface of the substrate 1. In an example shown in FIG. 4, the isolation region 9 is configured with an n-type semiconductor region. A concentration of n-type impurities in the isolation region 9 is larger than the concentration of the p-type impurities in the p-type semiconductor region 4, for example.

In the embodiment, the effect similar to that in the first embodiment can be obtained.

In the first embodiment to the third embodiment, for example, semiconductor regions may be formed on an SOI substrate and then the diodes D may be separated by performing dry-etching between the respective diodes D in addition to the above-described configuration of the isolation region 9. In this case, a gap provided in the p-type semiconductor region 4 corresponds to the isolation region 9.

### Fourth Embodiment

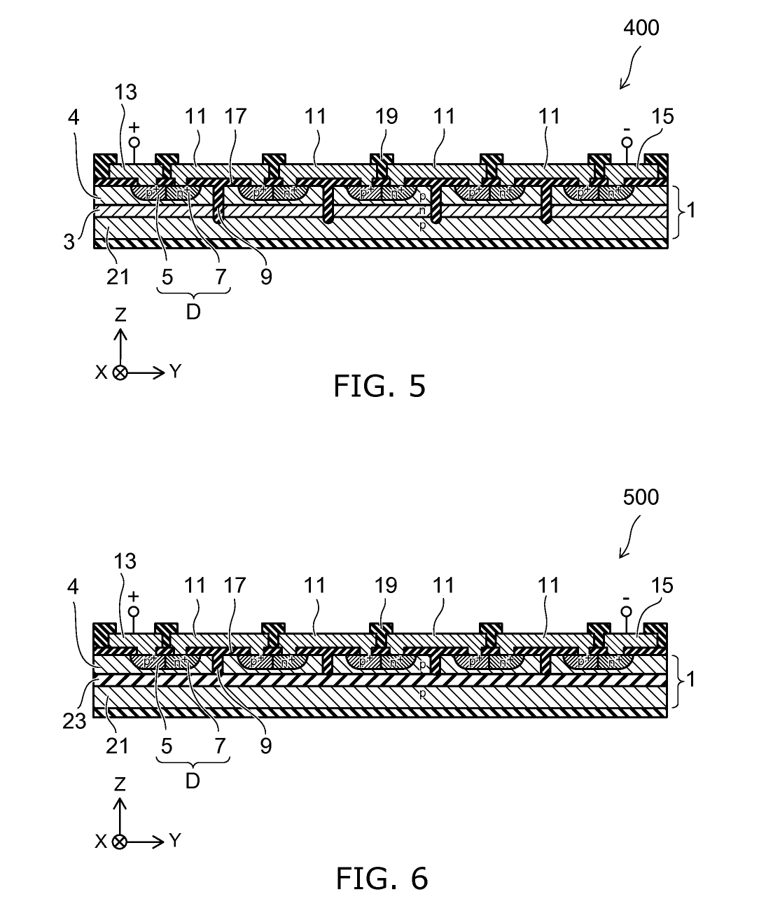

FIG. 5 is a cross-sectional view of a semiconductor device 400 according to a fourth embodiment.

The semiconductor device 400 according to the fourth embodiment is different from the semiconductor device 100 according to the first embodiment in that the semiconductor device 400 further includes a p-type semiconductor region 21 (fifth semiconductor region).

The n-type semiconductor region 3 is provided on the p-type semiconductor region 21. The isolation region 9 reaches the p-type semiconductor region 21 from the surface of the p-type semiconductor region 4. The isolation region 9 may reach the n-type semiconductor region 3 without reaching the p-type semiconductor region 21.

The semiconductor devices according to the respective embodiments are provided, for example, on a wiring board when the semiconductor device is incorporated with an electric circuit. At that time, an electrode is formed on a back side of the semiconductor device (interface opposite to the p-type semiconductor region 4 among interfaces of the n-type semiconductor region 3) and the cathode electrode 15 and the back electrode become short-circuited in some cases. In this case, a voltage is applied between the anode electrode 13 and the back electrode.

If a breakdown voltage between the anode electrode 13 and the back electrode decreases, a current flows in between the anode electrode 13 and the back electrode of the semiconductor device and the semiconductor device may or may not operate as a diode.

On the other hand, since the p-type semiconductor region 21 is provided, a p-n junction is formed between the n-type semiconductor region 3 and the p-type semiconductor region 21, and thus it is possible to increase the breakdown voltage between the anode electrode 13 and a back side of the semiconductor device.

According to the embodiment, a semiconductor device may operate further stably as a diode, compared to the first embodiment.

When the semiconductor region 3 is a p-type semiconductor region and the semiconductor region 4 is an n-type semiconductor region, the conductivity type of the semiconductor region 21 may be an n-type. That is, the semiconductor region 21 has a conductivity type different from that of the semiconductor region 3.

When the semiconductor region 3 is a p-type semiconductor region, the semiconductor region 21 is set to be an n-type semiconductor region, a p-n junction is formed between the semiconductor region 3 and the semiconductor region 21, and thus it is possible to increase the breakdown voltage between the anode electrode 13 and a back side of the semiconductor device.

### Fifth Embodiment

FIG. 6 is a cross-sectional view of a semiconductor device 500 according to a fifth embodiment.

The semiconductor device 500 according to the fifth embodiment is different from the semiconductor device 400 according to the fourth embodiment in that the semiconductor device 500 includes an insulating region 23 instead of the n-type semiconductor region 3.

The insulating region 23 is a region containing, for example, silicon oxide. The insulating region 23 is provided on the p-type semiconductor region 21. The p-type semiconductor region 4 is provided on the insulating region 23.

The isolation region 9 reaches the insulating region 23 from the surface of the p-type semiconductor region 4. The tip end of the isolation region 9 is positioned, for example, at a boundary part between the p-type semiconductor region 4 and the insulating region 23. The p-type semiconductor region 21 is provided under the insulating region 23.

The semiconductor device 500 is formed by, for example, bonding a substrate in which the p-type semiconductor region 4 is formed and a substrate in which the p-type semiconductor region 21 is formed. A surface on which the two substrates are bonded forms the insulating region 23.

The p-type semiconductor region 4 may be an n-type semiconductor region. The semiconductor region 21 may be an n-type semiconductor region.

According to the embodiment, the insulating region 23 is provided, the isolation region 9 reaches the insulating region 23, and thus it is possible to further suppress a current from flowing in the n⁺-type semiconductor region 7 which comes into contact with the cathode electrode 15 through the p-type semiconductor region 4 without flowing through the electrode 11, compared to the first embodiment.

### Sixth Embodiment

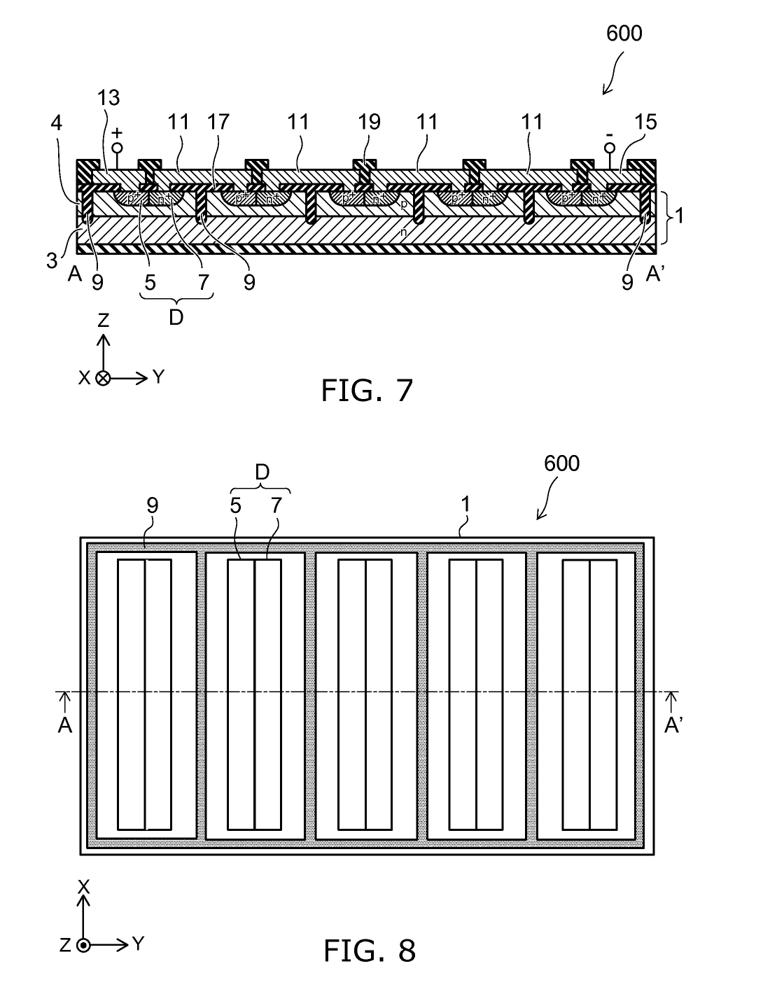

FIG. 7 is a cross-sectional view of a semiconductor device 600 according to a sixth embodiment.

FIG. 8 is a plan view of the semiconductor device 600 according to the sixth embodiment.

FIG. 7 is a cross-sectional view taken along line VII-VII in FIG. 8.

In FIG. 8, the insulating layer, the protective layer, the electrode, and the like are omitted so as to describe a structure of the isolation region 9 in a plan view.

The semiconductor device 600 according to the sixth embodiment is different from the semiconductor device 100 according to the first embodiment in that the isolation region 9 is also provided on the outer circumference of the semiconductor device 100 in order to surround the plurality of the diodes D.

The p-type semiconductor regions 4 where the diodes D are respectively provided are separated from end portions of the substrate 1 in the X-direction and the Y-direction by the isolation region 9. That is, the isolation region 9 is provided between the p-type semiconductor region 4 which is provided on the end portion of the substrate 1 in the X-direction and the end portion of the substrate 1 in the Y-direction and the p-type semiconductor region 4 at which the diode D is provided.

When a plurality of semiconductor devices are fabricated on one substrate, and then the substrate is cut to be separated into the plurality of semiconductor devices, a plurality of defects occur on a cross section of the substrate. As described above, an electrode is formed on the back side of the semiconductor device, and the cathode electrode 15 and the back electrode become short-circuited when the semiconductor device is provided on the wiring board in some cases.

If there are many defects on the cross section of the substrate (end surface of the semiconductor device), when a voltage is applied between the anode electrode 13 and the back electrode, a current flows in the vicinity of the end surface of the semiconductor device, and thus the semiconductor device may operate unstably as a diode.

On the other hand, according to the embodiment, in the p-type semiconductor region 4, the isolation region 9 causes the p⁺-type semiconductor region 5 connected to the anode electrode 13 and the end surface of the semiconductor device 600 to be separated. Even when a voltage is applied between the anode electrode 13 and the back side of the semiconductor device 600, it is possible to suppress a current from flowing in the vicinity of the end surface of the semiconductor device 600 and it is possible for the semiconductor device 600 to stably operate as a diode.

The isolation region 9 according to the embodiment may be applied to, for example, the above-described second embodiment to the fifth embodiment in addition to the first embodiment.

When the semiconductor region 3 is a p-type semiconductor region and the semiconductor region 4 is an n-type semiconductor region, a voltage which is applied between the anode electrode 13 and the back electrode is a reversed voltage with respect to a p-n junction of the semiconductor region 3 and the semiconductor region 4. When the semiconductor region 3 is a p-type semiconductor region and the semiconductor region 4 is an n-type semiconductor region, it is possible to further suppress a current from flowing in the vicinity of the end surface of the semiconductor device 600 and it is possible for the semiconductor device 600 to stably operate as a diode, compared to a case where the semiconductor region 3 is an n-type semiconductor region and the semiconductor region 4 is a p-type semiconductor region.

### Seventh Embodiment

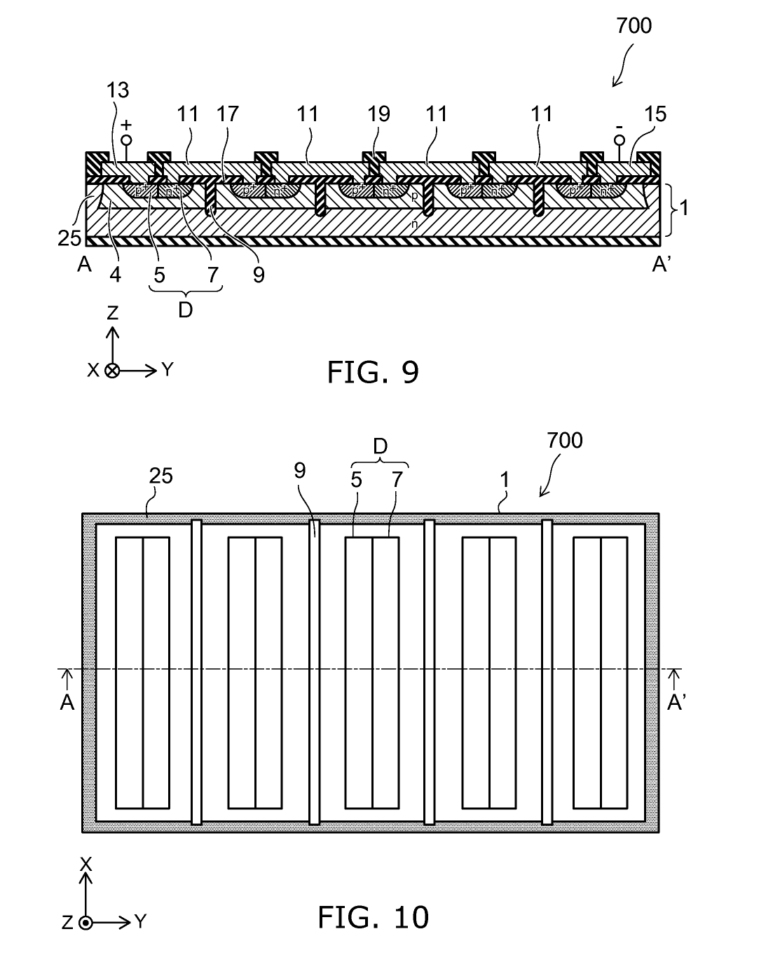

FIG. 9 is a cross-sectional view of a semiconductor device 700 according to a seventh embodiment.

FIG. 10 is a plan view of the semiconductor device 700 according to the seventh embodiment.

FIG. 9 is a cross-sectional view taken along line IX-IX in FIG. 10.

In FIG. 10, the insulating layer, the protective layer, the electrode, and the like are omitted so as to describe a structure of the isolation region 9 and an n-type semiconductor region 25 in a plan view.

The semiconductor device 700 according to the seventh embodiment is different from the semiconductor device 600 according to the sixth embodiment in that a part of the isolation region 9 is configured with the n-type semiconductor region 25. Specifically, the n-type semiconductor region 25 is provided instead of a part of the isolation region 9 provided on the outer circumference of the substrate 1.

The n-type semiconductor region 25 is a semiconductor region which has a conductivity type opposite to the conductivity type of the p-type semiconductor region 4. When the semiconductor region 4 is an n-type semiconductor region, the conductivity type of the semiconductor region 25 may be a p-type.

The n-type semiconductor region 25 is provided to surround the plurality of the diodes D. A concentration of n-type impurities in the n-type semiconductor region 25 is larger than the concentration of the p-type impurities in the p-type semiconductor region 4.

As shown in FIG. 10, the part of the isolation region 9 is provided in the n-type semiconductor region 25.

The n-type semiconductor region 25 is provided and thus when a voltage is applied between the anode electrode 13 and the back side of the semiconductor device 700, it is possible to suppress a current from flowing in the vicinity of an end surface of the semiconductor device 700 and it is possible for the semiconductor device 700 to stably operate as a diode, similarly to the sixth embodiment.

The n-type semiconductor region 25 may be applied to, for example, the above-described second embodiment to the fifth embodiment in addition to the first embodiment.

### Eighth Embodiment

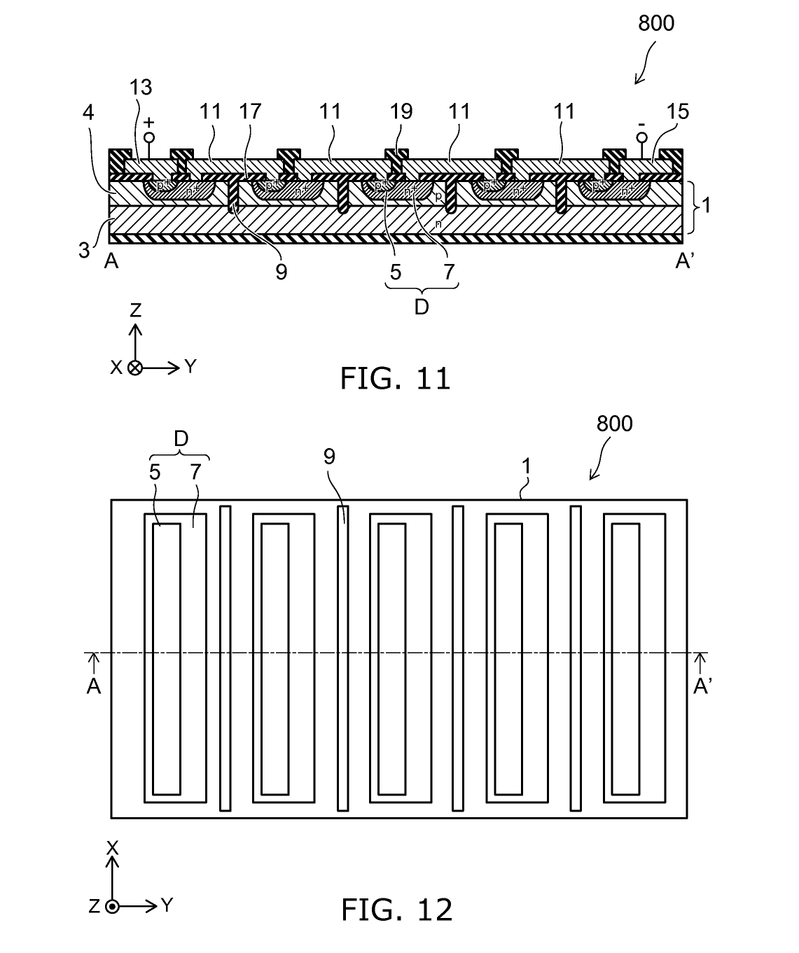

FIG. 11 is a cross-sectional view of a semiconductor device 800 according to an eighth embodiment.

FIG. 12 is a plan view of the semiconductor device 800 according to the eighth embodiment.

FIG. 11 is a cross-sectional view taken along line XI-XI in FIG. 12.

In FIG. 12, the insulating layer, the protective layer, the electrode, and the like are omitted so as to describe a structure of the p⁺-type semiconductor region 5 and the n⁺-type semiconductor region 7 in a plan view.

The semiconductor device 800 according to the eighth embodiment has a different structure of the p⁺-type semiconductor region 5 and the n⁺-type semiconductor region 7 from that of the semiconductor device 100 according to the first embodiment.

The n⁺-type semiconductor region 7 is selectively provided on the p-type semiconductor region 4. The p⁺-type semiconductor region 5 is provided over the p-type semiconductor region 4 and on the n⁺-type semiconductor region 7. The p⁺-type semiconductor region 5 and the n⁺-type semiconductor region 7 are similar to those in the first embodiment in that the p⁺-type semiconductor region 5 and the n⁺-type semiconductor region 7 extend in the X-direction and a plurality of p⁺-type semiconductor regions 5 and n⁺-type semiconductor regions 7 are provided in the Y-direction.

The p⁺-type semiconductor region 5 is surrounded by the n⁺-type semiconductor region 7. That is, a dimension of the p⁺-type semiconductor region 5 in the Y-direction is smaller than a dimension of the n⁺-type semiconductor region 7 in the Y-direction. A dimension of the p⁺-type semiconductor region 5 in the X-direction is smaller than a dimension of the n⁺-type semiconductor region 7 in the X-direction. A dimension of the p⁺-type semiconductor region 5 in the Z-direction orthogonal to the Y-direction and the X-direction is smaller than a dimension of the n⁺-type semiconductor region 7 in the Z-direction.

In the embodiment, the effect similar to that in the first embodiment can be obtained.

It is possible for the semiconductor device 800 to stably operate as a diode by combination with the semiconductor device according to the sixth embodiment or the seventh embodiment.

### Ninth Embodiment

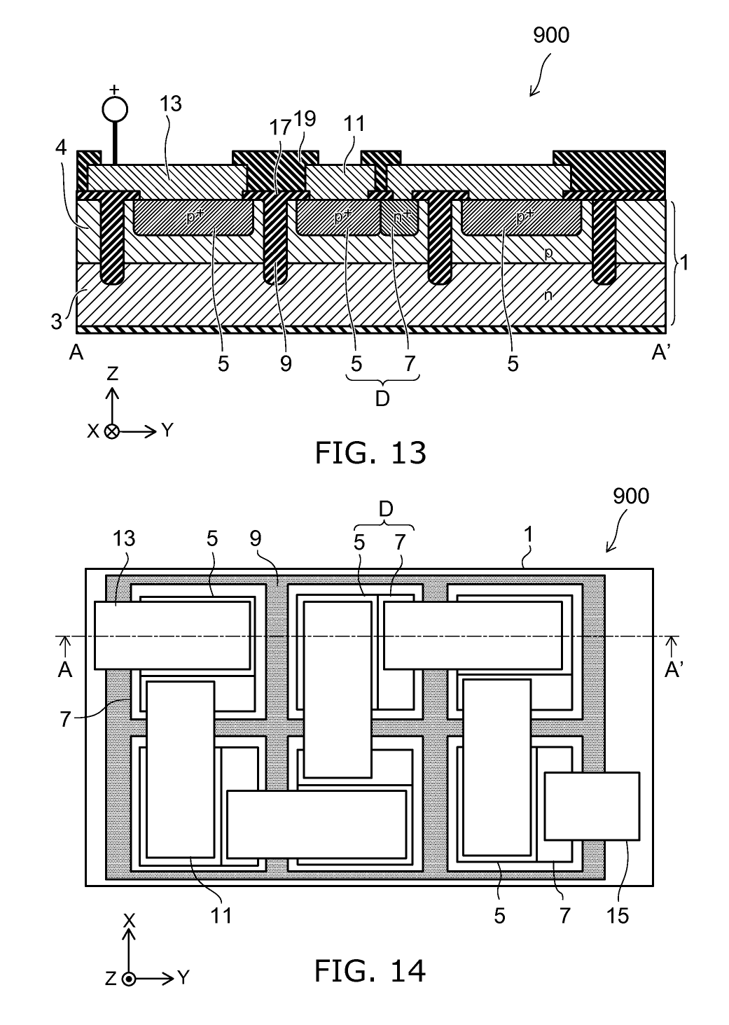

FIG. 13 is a cross-sectional view of a semiconductor device 900 according to a ninth embodiment.

FIG. 14 is a plan view of the semiconductor device 900 according to the ninth embodiment.

FIG. 13 is a cross-sectional view taken along line XIII-XIII in FIG. 14.

In FIG. 14, the insulating layer, the protective layer, and the like are omitted.

The semiconductor device 900 according to the ninth embodiment has a different arrangement of the diodes D, the electrode 11, and the like from that of the semiconductor device 100 according to the first embodiment.

In the first embodiment, the p⁺-type semiconductor region 5, the n⁺-type semiconductor region 7, and the electrode extend in the X-direction and a plurality of p⁺-type semiconductor regions 5, n⁺-type semiconductor regions 7, and electrodes are provided in the Y-direction. On the other hand, in the ninth embodiment, the diode includes the p⁺-type semiconductor region 5 and the n⁺-type semiconductor region 7 and a plurality of the diodes D are provided in the Y-direction and the X-direction.

The isolation region 9 is also provided between the adjacent diodes D in the embodiment. The isolation region 9 is provided to surround the plurality of the diodes D.

A part of the electrode 11 extends in the X-direction and another part of the electrode 11 extends in the Y-direction. The electrode 11 connects the p⁺-type semiconductor region 5 adjacent to the isolation region 9 with the n⁺-type semiconductor region 7. The electrode 11 is provided so as for the plurality of the diodes D to be connected in series.

When viewed in the Z-direction (in a plan view), an area of the p⁺-type semiconductor region 5 is larger than an area of the n⁺-type semiconductor region 7. In this manner, it is possible to increase a contact area of the p⁺-type semiconductor region 5 with the electrode 11 and a contact area of the n⁺-type semiconductor region 7 with the electrode 11. It is possible to form a substantially uniform contact area of the diode D with the electrode 11 in the respective diode D.

In the embodiment, the effect similar to that in the first embodiment can be obtained.

### Tenth Embodiment

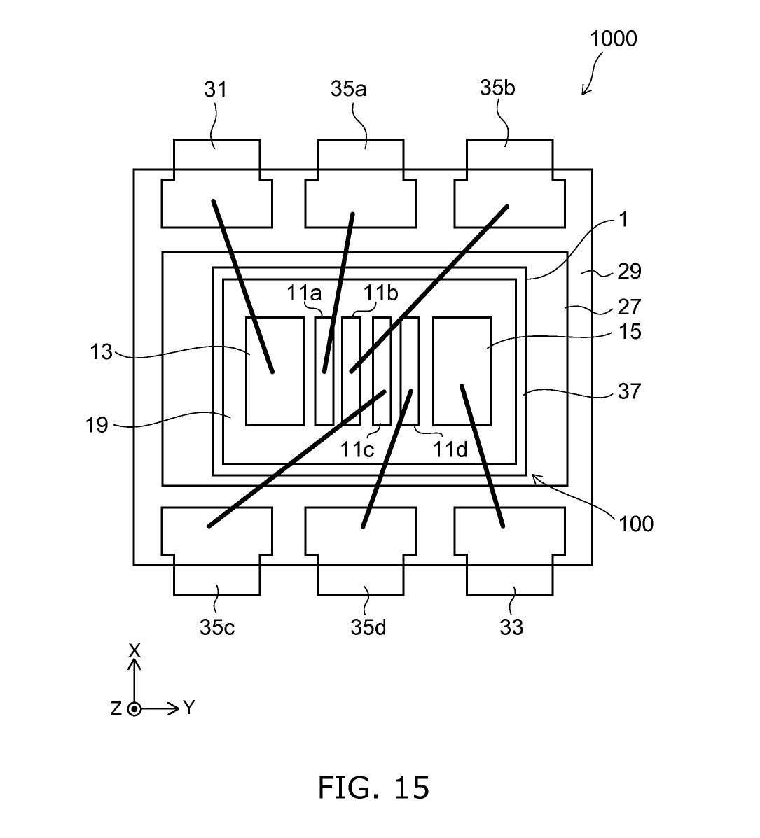

FIG. 15 is a plan view of a semiconductor device 1000 according to a tenth embodiment.

The semiconductor device 1000 is obtained by packaging the semiconductor device 100 according to the first embodiment.

The semiconductor device 1000 further includes a frame 27, a sealing member 29, an anode terminal 31, a cathode terminal 33, and terminals 35a to 35d in addition to the semiconductor device 100 according to the first embodiment. A dicing line 37 is formed on the substrate 1.

The semiconductor device 100 is placed on the frame 27 and is sealed by the sealing member 29.

The anode terminal 31 is connected to the anode electrode 13.

The cathode terminal 33 is connected to the cathode electrode 15.

The terminals 35a to 35d are respectively connected to electrodes 11a to 11d and each electrode connects the adjacent diodes D.

The semiconductor device 1000 includes the terminals 35a to 35d connected to the electrodes 11a to 11d and thus it is possible to select the number of the diodes D which are connected in series by matching the thermal dependency of the breakdown voltage in a Zener diode connected to the semiconductor device 1000. For example, when two diodes are connected in series and connected to the outside of the device, the anode terminal 31 and the terminal 35b may be connected to an external terminal. Alternatively, the terminal 35c and the cathode terminal 33 may be connected to an external terminal.

According to the embodiment, it is possible to easily adjust the thermal dependency of a drop voltage in the semiconductor device 1000 by matching the thermal dependency of the breakdown voltage in the Zener diode connected to the semiconductor device 1000.

### Eleventh Embodiment

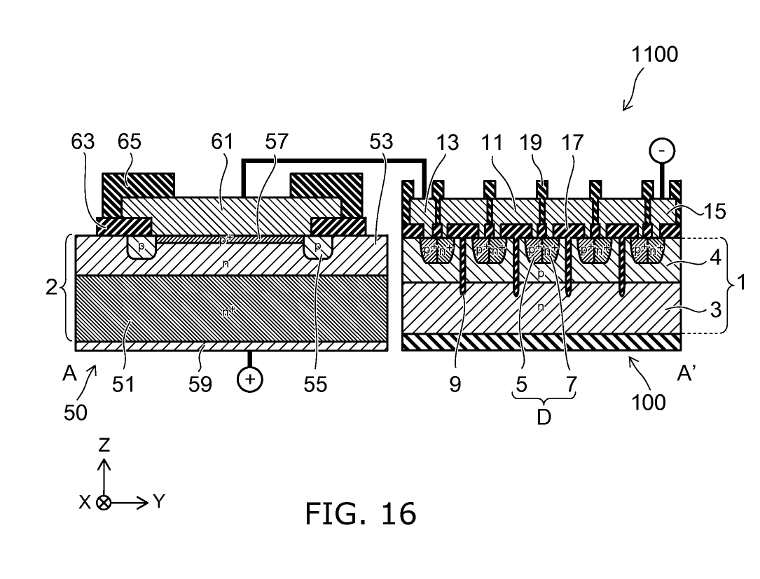

FIG. 16 is a cross-sectional view of a semiconductor device 1100 according to a eleventh embodiment.

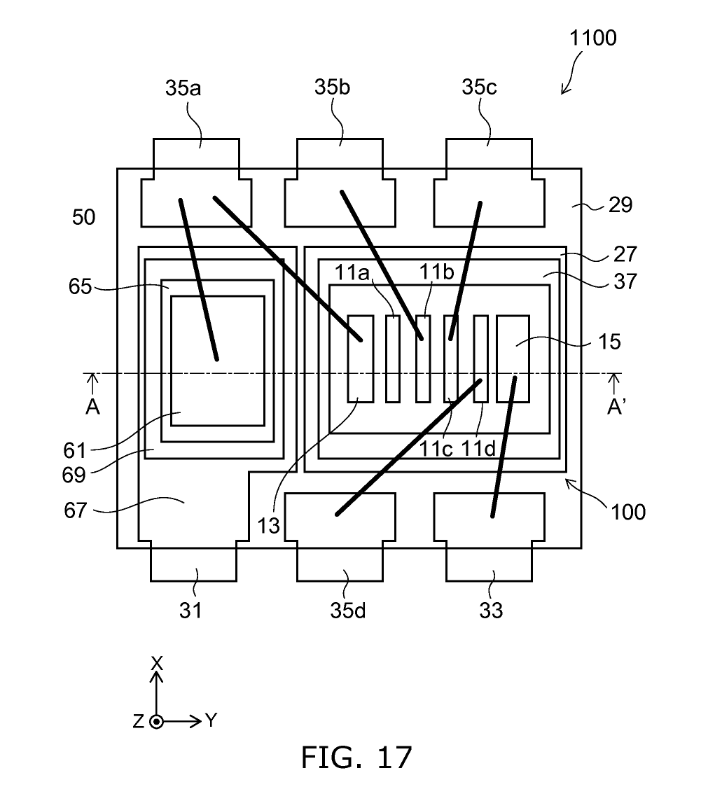

FIG. 17 is a plan view of the semiconductor device 1100 according to the eleventh embodiment.

FIG. 16 is a cross-sectional view taken along line XVI-XVI in FIG. 17.

In FIG. 16, the sealing member for packaging, the frame, the dicing line, and the like are omitted.

The semiconductor device 1100 connects a semiconductor device 50 with the semiconductor device 100 according to the first embodiment and is packaged.

The semiconductor device 1100 includes the semiconductor device 50, the semiconductor device 100, the frame 27, the sealing member 29, the cathode terminal 31 (first terminal), the anode terminal 33 (second terminal), the terminals 35a to 35d, and a frame 67.

The semiconductor device 50 includes a semiconductor substrate 2, a cathode electrode 59 (fourth electrode), an anode electrode 61 (fifth electrode), an insulating layer 63, and a protective layer 65. The semiconductor substrate 2 includes an n⁺-type semiconductor region 51, an n-type semiconductor region 53, a p-type semiconductor region 55, and a p⁺-type semiconductor region 57.

The semiconductor device 1100 according to the embodiment may be used as a Zener diode. The semiconductor device 100 has a configuration similar to that in the first embodiment. However, the anode terminal and the cathode terminal are opposite to the configuration of the first embodiment.

The dicing line 37 is formed on the substrate 1. A dicing line 69 is formed on the semiconductor substrate 2 (simply refer to substrate 2 below).

The n-type semiconductor region 53 is provided on the n⁺-type semiconductor region 51. The n⁺-type semiconductor region 51 is in contact with the cathode electrode 59. The n⁺-type semiconductor region 51 is not necessary for the embodiment. However, the n⁺-type semiconductor region 51 is desired to be provided in order to reduce electric resistance between the cathode electrode 59 and the semiconductor region coming into contact with the cathode electrode 59.

The p-type semiconductor region 55 and the p⁺-type semiconductor region 57 are provided on the n-type semiconductor region 53. The p-type semiconductor region 55 is provided to surround the p⁺-type semiconductor region 57.

The anode electrode 61 is in contact with the p⁺-type semiconductor region 57. The insulating layer 63 is provided on the p-type semiconductor region 55 at an outer circumference of the anode electrode 61. The p-type semiconductor region 55 is not necessary for the embodiment. However, it is possible to reduce an electric field intensity at an outer circumference of the n-type semiconductor region 53 by providing the p-type semiconductor region 55 with an annular shape under the insulating layer 57.

The anode electrode 61 is connected to the cathode electrode 13 of the semiconductor device 100.

The protective layer 65 is provided on the anode electrode 61 and on the insulating layer 63.

The semiconductor device 50 is provided on the frame 67. The frame 67 is connected to the cathode terminal 31. The anode electrode 61 is connected to the terminal 35a.

The electrode 11b is connected to the terminal 35b (third terminal). The electrode 11c is connected to the terminal 35c. The electrode 11d is connected to the terminal 35d. The anode electrode 15 is connected to the anode terminal 33.

In the semiconductor device 50, a Zener diode is configured by the n⁺-type semiconductor region 51, the n-type semiconductor region 53, the p-type semiconductor region 55, and the p⁺-type semiconductor region 57.

That is, the semiconductor device 1100 has a structure in which the semiconductor device 50 which is the Zener diode and the plurality of forward diodes D are connected in series.

If the temperature increases, the breakdown voltage increases generally in the Zener diode having a breakdown voltage of approximately 5 V or more. As an example, when the semiconductor device 50 is a Zener diode having a breakdown voltage of 16.5 V, if the temperature increases by 1° C., the breakdown voltage increases by 12.5 mV. If the temperature increases by 1° C., the breakdown voltage decreases by 2.5 mV in a forward diode. Accordingly, it is possible to compensate for the thermal dependency of the Zener diode by connecting a forward diode to the Zener diode. However, just one forward diode is insufficient for compensating for the thermal dependency of the above-described Zener diode having a breakdown voltage of 16.5 V.

The semiconductor device 100 has a structure in which the plurality of the forward diodes are connected in series. For example, the semiconductor device 100 shown in FIG. 16 has a structure in which five forward diodes are connected in series. When the forward diodes are connected in series, the thermal dependency of the respective forward diodes is summed. Accordingly, in an example shown in FIG. 16, if the temperature of the semiconductor device 100 increases by 1° C., the drop voltage of a forward diode decreases by 12.5 mV. Consequently, the thermal dependency of the Zener diode having a breakdown voltage of 16.5 V is reduced due to the thermal dependency of the semiconductor device 100.

The forward diode has a drop voltage of approximately 0.7 V. In the above-described example, the breakdown voltage is 16.5 V due to the Zener diode and the summation of the drop voltage is approximately 3.5 V due to the forward diode. When a voltage exceeding the breakdown voltage of the Zener diode is applied, the breakdown voltage of approximately 20 V occurs in the entirety of the semiconductor device 1100.

Accordingly, the semiconductor device 1100 has a breakdown voltage of 20 V and thus it is possible to use the semiconductor device 1100 as a Zener diode having small thermal dependency.

According to the embodiment, it is possible to obtain a Zener diode having a large drop voltage and small thermal dependency.

The semiconductor device 1100 has the terminals 35b to 35d respectively connected to the electrode 11 of the semiconductor device 100. Accordingly, it is possible to select the number of the forward diodes connected in series in accordance with the breakdown voltage of the semiconductor device 50.

It is possible to easily adjust the thermal dependency of a drop voltage in the semiconductor device 100 by matching the thermal dependency of the breakdown voltage in the semiconductor device 50.

### Twelfth Embodiment

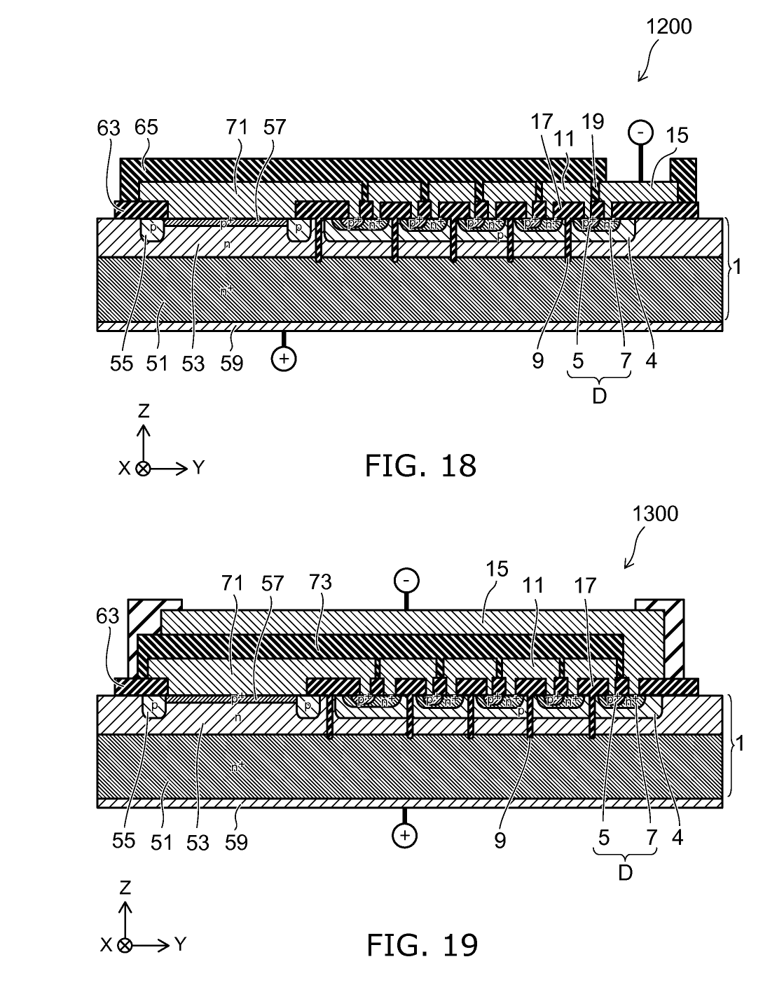

FIG. 18 is a cross-sectional view of a semiconductor device 1200 according to a twelfth embodiment.

The semiconductor device 1200 according to the twelfth embodiment is mainly different from the semiconductor device 1100 according to the eleventh embodiment in that the semiconductor device 50 and the semiconductor device 100 are formed on one substrate.

In the substrate 1, the n-type semiconductor region 53 is provided on the n⁺-type semiconductor region 51. The p-type semiconductor region 4, the p-type semiconductor region 55, and the p⁺-type semiconductor region 57 are provided on the n-type semiconductor region 53.

The p⁺-type semiconductor region 5 is provided on the n⁺-type semiconductor region 7. The p⁺-type semiconductor region 5 is surrounded by the n⁺-type semiconductor region 7. Thus, a current is suppressed from flowing between the p⁺-type semiconductor region 5 and the n-type semiconductor region 53 through the p-type semiconductor region 4.

The isolation region 9 is provided to reach the n⁺-type semiconductor region 51 from a surface of the p-type semiconductor region 4 (surface of the substrate 1) as an example.

An electrode 71 is connected to the p⁺-type semiconductor region 57 and the p⁺-type semiconductor region 5 which is provided on the most anode side among the plurality of the p⁺-type semiconductor region 5. The electrode 71 is a cathode electrode of the semiconductor device 50 and an anode electrode of the semiconductor device 100. The semiconductor device 50 and the semiconductor device 100 are connected in series through the electrode 71.

According to the embodiment, because the semiconductor device 50 and the semiconductor device 100 are provided on one substrate, compared to the eleventh embodiment, it is possible to further reduce the size of a semiconductor device including the semiconductor device 50 and the semiconductor device 100.

At this time, the p-type semiconductor region 4 is set to a p-type semiconductor region, and thus the p-type semiconductor region 4 may be provided on the n-type semiconductor region 53 and the diode D may be formed on the p-type semiconductor region 4. It is possible to further reduce the size of the semiconductor device 1200 by providing the p-type semiconductor region 4 and the diode D on the n-type semiconductor region 53.

### Thirteenth Embodiment

FIG. 19 is a cross-sectional view of a semiconductor device 1300 according to a thirteenth embodiment.

The semiconductor device 1300 according to the thirteenth embodiment has a different shape of the cathode electrode 15 from that of the semiconductor device 1200 according to the twelfth embodiment, mainly.

An insulating layer 73 is provided on the electrode 11 and the electrode 71. The insulating layer 73 covers the electrode 11 and the electrode 71. For example, silicon oxide may be used as a material of the insulating layer 73.

The cathode electrode 15 comes into contact with the n⁺-type semiconductor region 7 of one diode D and is provided on the insulating layer 73.

According to the embodiment, it is possible to increase an area of the cathode electrode 15 and to suppress contact failure from occurring when an external terminal is connected to the cathode electrode 15, compared to the twelfth embodiment. Additionally, it is possible to connect the cathode electrode 15 with the external terminal at a desired position on the substrate 1.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a first semiconductor region;
a plurality of second semiconductor regions selectively provided on the first semiconductor region, the second semiconductor region having a first conductivity type;
a plurality of third semiconductor regions selectively provided on the first semiconductor region, each of the third semiconductor regions being adjacent to each of the second semiconductor regions and the third semiconductor region having a second conductivity type;
an isolation region provided in the first semiconductor region, the isolation region positioned between the adjacent second semiconductor regions and the adjacent third semiconductor regions;
a first electrode connected to the second semiconductor region and the third semiconductor region which are adjacent to the isolation region;
a second electrode connected to the second semiconductor region; and
a third electrode connected to the third semiconductor region.

2. The device according to claim 1, further comprising:
a fourth semiconductor region having a different conductivity type from that of the first semiconductor region,
wherein the first semiconductor region is provided on the fourth semiconductor region.

3. The device according to claim 2,
wherein a part of the isolation region is surrounding by the fourth semiconductor region.

4. The device according to claim 1,
wherein the isolation region includes
an insulating layer having at least one part which is connected to the first semiconductor region, and
a conductive layer which has at least one part provided in the first semiconductor region through the insulating layer and is connected to the first electrode.

5. The device according to claim 1,
wherein the isolation region is a semiconductor region having a conductivity type different from that of the first semiconductor region.

6. The device according to claim 1,
wherein a part of the isolation region is provided to surround the plurality of second semiconductor regions and the plurality of third semiconductor regions.

7. The device according to claim 2, further comprising:
a fifth semiconductor region having the first conductivity type,
wherein the first semiconductor region has the first conductivity type,
the fourth semiconductor region has the second conductivity type, and
the fourth semiconductor region is provided on the fifth semiconductor region.

8. The device according to claim 1,
wherein the first electrode, the second semiconductor region, and the third semiconductor region extend in a first direction,
the second semiconductor region is adjacent to the third semiconductor region in a second direction orthogonal to the first direction, and
the second semiconductor regions and the third semiconductor regions are arrayed in the second direction.

9. The device according to claim 1, further comprising:
a first terminal connected to the second electrode;
a second terminal connected to the third electrode; and
a sealing member of sealing the first electrode.

10. The device according to claim 9, further comprising:
a third terminal connected to the first electrode.

11. The device according to claim 1, further comprising:
a sixth semiconductor region having the second conductivity type;
a seventh semiconductor region provided on the sixth semiconductor region, the seventh semiconductor region having the first conductivity type;
a fourth electrode connected to the sixth semiconductor region; and
a fifth electrode connected to the seventh semiconductor region,
wherein the second electrode is connected to the fifth electrode.

12. The device according to claim 11, further comprising:
an eighth semiconductor region having the second conductivity type,
wherein the sixth semiconductor region is provided between the seventh semiconductor region and the eighth semiconductor region, and
a density of the second conductivity type carrier in the eighth semiconductor region is larger than a density of the second conductivity type carrier in the sixth semiconductor region.

13. The device according to claim 11, further comprising:
a first terminal connected to the third electrode;
a second terminal connected to the fourth electrode; and
a sealing member of sealing the first electrode, the second electrode, the third electrode, the fourth electrode, and the fifth electrode.

14. The device according to claim 13, further comprising:
a third terminal connected to the first electrode.

15. The device according to claim 11,
wherein the plurality of second semiconductor regions, the plurality of third semiconductor regions, the sixth semiconductor region, and the seventh semiconductor region are provided on a same substrate.

16. The device according to claim 11,
wherein the first semiconductor region is a semiconductor region having the first conductivity type, and
the first semiconductor region is provided on the sixth semiconductor region.

17. The device according to claim 16, further comprising:
an eighth semiconductor region having the second conductivity type,
wherein the sixth semiconductor region is provided between the seventh semiconductor region and the eighth semiconductor region, and
a density of the second conductivity type carrier in the eighth semiconductor region is larger than a density of the second conductivity type carrier in the sixth semiconductor region.

18. The device according to claim 17,
wherein a part of the isolation region is surrounding by the eighth semiconductor region.
